(19) United States
(12) Patent Application Publication
(10) Pub. No.: US 2016/0056121 A1
(43) Pub. Date: Feb. 25, 2016

(54) Metallized electric component

(71) Applicant: Infineon Technologies AG, Neubiberg (DE)

(72) Inventors: Joachim MAHLER, Regensburg (DE); Guenther KOLMEDER, Altdorf (DE); Chen Wen LEE, Ipoh Perak (MY)

(21) Appl. No.: 14/830,408

(22) Filed: Aug. 19, 2015

(30) Foreign Application Priority Data
Aug. 20, 2014 (DE) 10 2014 111 895.2

(51) Int. Cl. H01L 23/00; C22C 5/02; C22C 5/06

(52) U.S. Cl. CPC H01L 24/45; H01L 24/05; H01L 24/48; C22C 5/06; C22C 5/02; H01L 2224/04042; H01L 2224/05082; H01L 2224/05099; H01L 2224/45147; H01L 2224/4556; H01L 2224/45565; H01L 2224/48159; H01L 2924/01079; H01L 2924/01047; H01L 2924/0132; H01L 2924/01022; H01L 2924/35121

(57) ABSTRACT

Various embodiments provide a metallized electric component for an electronic module, wherein the metallized electric component comprises a conductive electric element; and a metallization structure arranged over the conductive electric element and comprising at least a surface metallization layer, wherein the surface metallization layer comprises gold and silver and has a thickness between 2 nm and 100 nm.

### TECHNICAL FIELD

Various embodiments relate to a metallized electric component, in particular a metallized chip or metallized bonding wire, and an electronic module.

### BACKGROUND

A variety of packaged electronic modules are known which typically comprise a plurality of electric elements, e.g. electronic chips or dies or simple bonding wires. In general, the plurality of electric or electronic elements or components are electrically contacted with each other. For improving these electrical contacts often metallization layers are disposed on contacts, contact pads or contact layers of the electric components before these contacts are electrically connected to each other or to external components or elements.

For example, US 2011/0115068 A1 discloses a power semiconductor module including an insulation layer having a top side on which a metallization layer is arranged. Furthermore, the module comprises a power semiconductor chip having a chip upper metallization of a thickness of at least one micrometer which is used to connect the chip to the metallization layer of the insulation layer and thus forming an inner intermediate connection layer between two elements of the module.

An example of metallized wires is known from US 2013/0233594 A1 disclosing a wire having a silver-gold-palladium core of a diameter of about 10 to 50 micrometer and a plating layer of a thickness between 1 nm to 5 micrometer. For example the plating layer comprises at least one layer of pure gold, pure palladium or a gold-palladium alloy.

One issue when using electronic modules is that these electronic modules are subjected to stress, e.g. thermal stress or mechanical stress, during operation, which may result in delamination of layers and/or component, e.g. a delamination of a mold compound encapsulating the electric/electronic component of the electronic module. Such a delamination may cause cracks or breaks of electrical contacts or connectors in the electronic module and thus cause failures of the whole electronic module.

### SUMMARY

Various embodiments provide a metallized electric component for an electronic module, wherein the metallized electric component comprises a conductive electric element; and a metallization structure arranged over the conductive electric element and comprising at least a surface metallization layer, wherein the surface metallization layer comprises an alloy of gold and silver and has a thickness between 1 nm and 100 nm.

Furthermore, various embodiments provide an electronic module comprising a metallized electric component according to an exemplary embodiment; and an encapsulation at least partially encapsulating the metallized electric component.

Moreover, various embodiments provide a bonding wire for an electronic module, wherein the bonding wire comprises a copper core; and an outer corrosion protection layer comprising as a material at least one material selected out of the group consisting of titanium and an alloy of gold and silver, wherein the outer corrosion protection layer is arranged around the copper core.

### BRIEF DESCRIPTION OF THE DRAWINGS

In the drawings, like reference characters generally refer to the same parts throughout the different views. The drawings are not necessarily to scale. Instead emphasis is generally being placed upon illustrating the principles of the invention. In the following description, various embodiments are described with reference to the following drawings, in which:

FIG. 1 schematically depicts a metallized chip according to an exemplary embodiment;

FIG. 2 schematically depicts a detail of a metallized chip according to an exemplary embodiment;

FIG. 3 schematically depicts a metallized bonding wire according to an exemplary embodiment;

FIG. 4 schematically depicts a metallized bonding wire according to another exemplary embodiment; and

FIG. 5 schematically depicts a metallized bonding wire according to yet another exemplary embodiment.

### DETAILED DESCRIPTION

In the following further exemplary embodiments of a metallized electric component for an electronic module, of a metallized electronic chip, of a metallized bonding wire, a method of manufacturing an metallized electric component and an electronic module comprising a metallized electric component will be explained. It should be noted that the description of specific features described in the context of one specific exemplary embodiment may be combined with others exemplary embodiments as well.

The word “exemplary” is used herein to mean “serving as an example, instance, or illustration”. Any embodiment or design described herein as “exemplary” is not necessarily to be construed as preferred or advantageous over other embodiments or designs.

Various exemplary embodiments provide a surface metallization layer which comprises gold and silver as compounds or which is formed or consist of gold and silver, in particular an alloy of gold and silver.

Furthermore, various embodiments provide a metallized chip, comprising an electronic chip; and a surface metallization layer arranged over or on the electronic chip and comprising gold and silver, in particular an alloy comprising gold and silver.

Moreover, various embodiments provide a bonding wire for an electronic module, wherein the bonding wire comprises a metallic core; and a surface metallization layer comprising gold and silver, in particular an alloy of gold and silver.

Furthermore, various embodiments provide a method of manufacturing a metallized chip, wherein the method comprises providing an electronic chip comprising electric contacts or contact layers; and forming a surface metallization layer comprising gold and silver (gold/silver alloy) over at least one of the electric contacts. In particular, the method may comprise an optional step of forming a sub-layer comprising titanium over the electric contact before the surface metallization layer is formed.

The term “metallization layer” may particularly denote any layer which forms an electrically conductive structure which may be suitable to provide an improved electrical contact between the portions of the electric element, e.g. chip or bonding wire, on which it is deposited or formed and a conductive path external to the electric element, e.g. a bonding wire or the like. Typically such metallization layers are formed on contacts, e.g. contact pads, of electronic chips, since it may be difficult to attach wires, leads or the like to the material of the contacts of the electronic chips or are used to protect the contacts. A metallization layer may also be formed on bonding wires or other electrically conductive components or elements. It should be noted that a (metallization) layer in general may form a continuous, solid or homogenous layer and may thus to be distinguished from a “porous layer”, for example, which comprises a high amount of voids and may thus be considered to be inhomogenous.

The term “outer metallization layer” or “surface metallization layer” may in particular denote a layer which forms the outer (top layer, bottom layer and/or outer sidewalls layers) surface of the metallization of an electric element or component, e.g. of a chip, to which an external contact, e.g. a bonding wire or the like, can be connected, or vice versa. It should be noted that the surface metallization layer may also act as a corrosion protection and may therefore be called a corrosion protection layer as well. In particular, the corrosion protection layer may have a thickness between 1 or 2 nm and 100 nm, particularly between 5 nm and 100 nm, preferably between 5 nm and 65 nm, and even more preferably between 5 nm and 50 nm.

In particular, the surface metallization layer may be directly formed on the electric contacts or one or several further electrically conductive layers may be formed between the electric contact and the surface metallization layer. It should be noted that the metallized electronic or semiconductor chip having the surface metallization layer attached or formed thereon may not be attached to a substrate, carrier or leadframe at that point in time the surface metallization layer is formed. That is, the surface metallization layer comprising gold and silver (or is formed by an alloy of gold and silver) may be formed on the chip before the electronic chip is attached to a substrate or carrier. In particular, the surface metallization layer may be formed on the electronic chip which has to be distinguished from a surface metallization layer which is formed on a substrate like a leadframe onto which afterwards an electronic chip is attached.

In particular, the thickness of the surface metallization layer may be in the range between 2 nm and 100 nm, preferably between 5 nm and 65 nm, and more preferably between 5 nm and 50 nm.

The use of a surface metallization layer comprising or consisting of gold and silver or a gold/silver alloy may particular be useful in case a molding compound is used to encapsulate the metallized electric component, e.g. chip or bonding wire, afterwards, since typical molding materials have a good or improved adhesion on gold/silver compounds or alloys. Furthermore, such a gold/silver layer may exhibit good bonding performance, e.g. a bonding wire or bond structure may be easily and reliably attached or bonded to the gold/silver metallization layer, which may lead to a high reliability of the whole metallized electric element (e.g. chip or even of an electronic module or structure) the metallized chip or bonding wire is used in or forms a part thereof. In particular, delamination, e.g. due to stress (thermal and/or mechanical), after a plurality of stress cycles, may be reduced.

In the following exemplary embodiments of the metallized electric component are described. However, the features and elements described with respect to these embodiments can be combined with exemplary embodiments of the method of manufacturing the metallized electric component, the electronic module, the metallized chip, and the metallized bonding wire.

According to an exemplary embodiment of the metallized electric component the metallization structure is palladium-free.

In particular, no palladium is present in the whole surface metallization layer or the whole multilayer structure. The term “palladium-free” may particularly denote the fact that the layer or structure does not comprise palladium in an intended amount or is willingly added to the material. However, some traces, contaminations or impurities of palladium may of course be possible. In particular, the non-intentional amount of palladium may be below a predetermined threshold, e.g. below 1% by mass, or even below 0.1% by mass or the like. The omitting of palladium, which is often used instead of lead, may lead to an improved corrosive resistance of a metallization structure, e.g. against sulfur or sulfur compounds. The provision of a palladium-free metallization structure may further have the advantage that a catalytic effect of the palladium with respect to organic component, e.g. a molding or encapsulation material, may be reduced or avoided. Thus, it may be possible that a later formed encapsulation of an electronic module, the metallized electric component is used in, may be attached more securely to the electric component, e.g. a chip, die or the like. Thus, also the (thermal and/or mechanical) stress resistance of the electronic module may be improved.

According to an exemplary embodiment of the metallized electric component the mass ratio between gold and silver in the surface metallization layer is in the range of 1 to 2 through 5 to 1.

That is, the amount of gold in the surface metallization layer or in the whole metallization structure may be between 33 mass % to 84 mass % (particular 40 mass % to 80 mass %) of a gold/silver alloy or compound. In other words, the surface metallization layer or the gold/silver layer of the metallization structure may comprise between 33 mass % to 84 mass % gold and between 67 mass % to 16 mass % of silver.

According to an exemplary embodiment of the metallized electric component the metallization structure comprises a sub-layer comprising titanium.

In particular, the main component of the sub-layer may be titanium or the sub-layer may even substantially consist of or consist of titanium. The titanium may in particular suitable to provide an adhesive promoting effect, i.e. function as an adhesion promoter. In particular, titanium may be a suitable adhesive or adhesion promoter in case a first sub-layer of the surface metallization layer comprises or consisting substantially of nickel onto which then the titanium sub-layer is formed before the outer gold/silver surface metallization layer is formed or deposited. Alternatively, the sub-layer comprising or consisting of titanium may be formed between the surface metallization layer and a copper layer used for the contacts or contact pads of the electronic chip. In particular, the sub-layer may be arranged between a chip and/or bonding wire forming or being part of the electronic component and the surface metallization layer.

According to an exemplary embodiment of the metallized electric component the sub-layer comprising titanium has a thickness between 1 nm and 20 nm.

In particular, the thickness of the titanium layer may be in the range between 1 nm and 15 nm, preferably between 2 nm and 10 nm.

According to an exemplary embodiment of the metallized electric component the electric element is an electronic chip. In particular, the electronic chip may be a semiconductor chip.

According to an exemplary embodiment of the metallized electric component the metallization structure comprises a sub-layer comprising titanium. In particular, the sub-layer may be arranged between the chip and the surface metallization layer.

According to an exemplary embodiment of the metallized electric component the electric element is a bonding wire.

According to an exemplary embodiment of the metallized electric component the bonding wire comprises a metallic core and the metallization structure is arranged around the metallic core.

According to an exemplary embodiment of the metallized electric component the metallic core comprises copper. In particular, the metallic core may substantially consist or consist of copper. That is, no intentionally added other elements or impurities may be present in the metallic core.

According to an exemplary embodiment of the metallized electric component the metallization structure comprises a sub-layer comprising titanium, which is arranged between the metallic core and the surface metallization layer.

In particular, the sub-layer may be a titanium layer, i.e. a layer wherein titanium is the main component of the layer or even the sub-layer substantially consists or consists of titanium. Such a titanium layer may in particular function as an adhesive promoter between the copper core and the metallization layer.

In the following exemplary embodiments of the electronic module are described. In particular, the encapsulation of the electronic module may comprise a molding material, e.g. an organic molding material.

According to an exemplary embodiment of the electronic module the metallized electric component is an electronic chip, wherein the electronic module further comprises a bonding wire bonded to the surface metallization layer.

According to an exemplary embodiment of the electronic module the electric component is a bonding wire, wherein the electronic module further comprises an electronic chip comprising a bond pad, wherein the bonding wire is bonded to the bond pad.

According to an exemplary embodiment of the bonding wire the outer corrosion protection layer comprises an alloy of gold and silver and a titanium layer is arranged between the copper core and the outer corrosion protection layer.

In particular, a corrosion protection layer or structure may be provided comprising the outer corrosion protection (sub)layer and an intermediate corrosion protection (sub)layer comprising or consisting of titanium, which may function as an adhesion promotion layer, for example.

According to an exemplary embodiment of the outer corrosion protection layer comprises an alloy of gold and silver, wherein the mass ratio between gold and silver in the surface metallization layer is in the range of 1 to 2 through 5 to 1.

In the following specific embodiments of the metallized electric component will be described in more detail with respect to the figures.

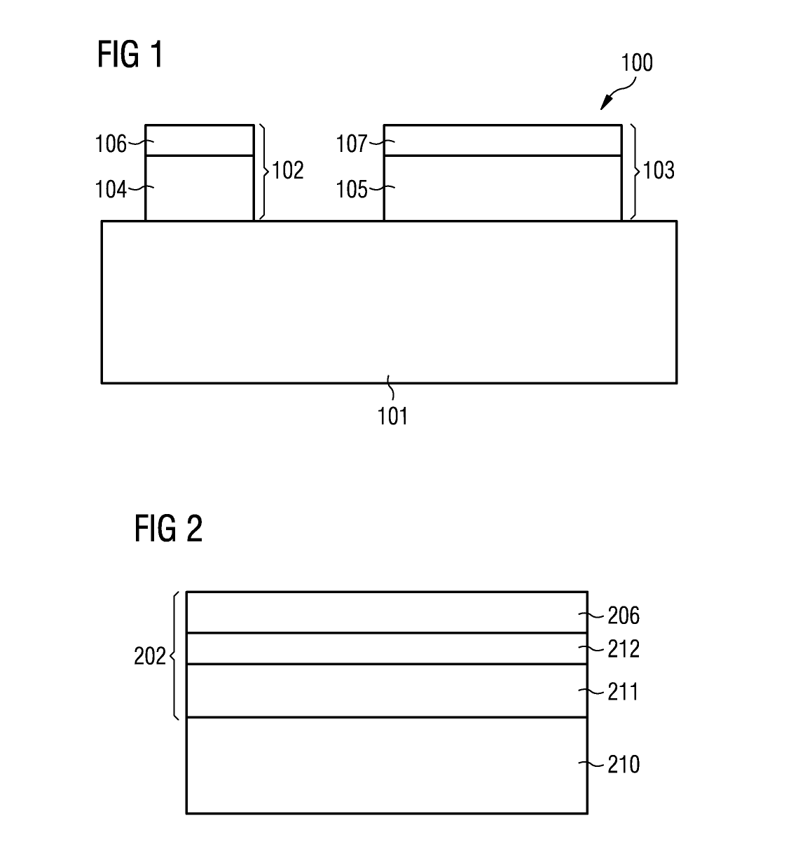

FIG. 1 schematically depicts a metallized chip according to an exemplary embodiment. In particular, FIG. 1 shows a metallized electronic chip 100 comprising a conductive electric element, like an electronic (semiconductor) chip, 101 having arranged thereon metallization structures 102 and 103 each comprising a respective first metallization sub-layer 104 and 105 which may be arranged directly on an upper surface of the conductive electric element (e.g. electronic chip) 101, e.g. on contact pads or connection layers of the electronic chip. An upper or outer layer of the metallization structures 102 and 103 is formed by a surface metallization layer 106 and 107, respectively. The surface metallization layers comprise gold and silver, in particular substantially consists of gold and silver, e.g. may comprise 33 mass % to 84 mass % while the remaining 67 mass % to 16 mass % may be formed by silver. In particular, it should be noted that the whole metallization structure is preferably free of palladium.

FIG. 2 schematically depicts a detail of a metallized chip according to an exemplary embodiment. In particular, FIG. 2 shows a contact layer 210 forming a contact area or contact terminal 210 of an electronic chip (not shown in FIG. 2). The contact area 210 may comprise copper, for example and may have a thickness in the range between 5 micrometer and 50 micrometer or the like. On the contact layer 210 a metallization structure 202 is formed or deposited comprising a plurality of sub-layers. In FIG. 2 three sub-layers 211, 212 and 206 are shown forming the metallization structure 202. In particular, a first sub-layer 211 formed or deposited on the contact layer is formed by a nickel layer having a thickness in the range of about 200 nm to 1,500 nm, while a second sub-layer 212 is formed by titanium and has a thickness of about 1 or 2 nm to 10 nm. It should be noted that the nickel layer is an optional layer and may be omitted.

The titanium layer 212 may act as an adhesive promoter between the nickel layer 211 and the surface metallization layer 206 formed on the titanium layer. The surface or outer metallization layer 206 comprises gold and silver and has a thickness in the range of about 5 nm to 65 nm, for example. Such a surface metallization layer may provide for a good adhesion in case a bonding wire, e.g. a copper and/or gold bonding wires, is connected to the metallization layer and at the same time may enable a reliable connection or fixing to a molding material used for an encapsulation of an electronic module, the metallized electronic chip is used in.

As can be seen in FIG. 2 the metallization structure 202 does not comprise a palladium layer and also in the sub-layers no palladium is used. Therefore, the resistance of the metallized and encapsulated electronic chip with respect to sulfur, e.g. present in the surrounding atmosphere, the molding material, or any other adhesive material, may be improved.

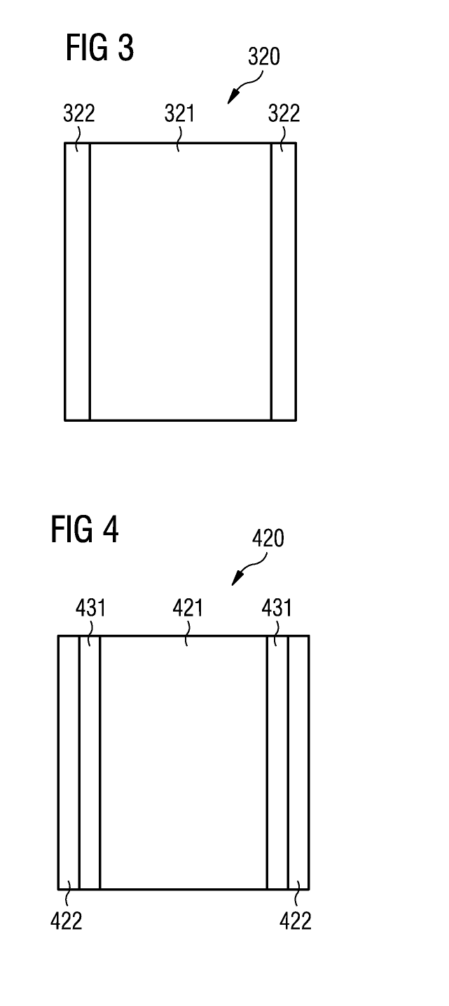

FIG. 3 schematically depicts a metallized bonding wire 320 according to an exemplary embodiment. In particular, the metallized bonding wire 320 comprises a metallic core 321 comprising or consisting of copper, for example. On the surface of the metallic core 321 a surface metallization layer or corrosion protection layer 322 is formed or deposited forming the outer surface of the bonding wire 320. The surface metallization layer 322 comprises gold and silver in the above mentioned ratio for example and has a thickness between about 5 nm and 50 nm, for example.

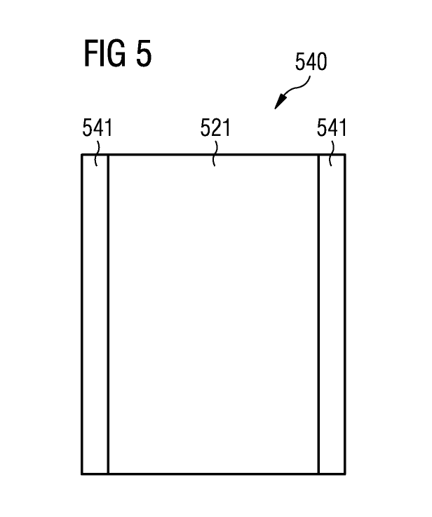

FIG. 4 schematically depicts a metallized bonding wire 420 according to another exemplary embodiment similar to the one shown in FIG. 3. In particular, the metallized bonding wire 420 comprises as well a metallic core 421 comprising or consisting of copper, for example. On the surface of the metallized bonding wire 420 a surface metallization layer or corrosion protection layer 422 is formed or deposited. The surface metallization layer 422 comprises gold and silver in the above mentioned ratio for example and has a thickness between about 5 nm and 50 nm, for example. In contrast to the bonding wire shown in FIG. 3 an additional sub-layer 431 is arranged between the metallic core 421 and the surface metallization layer 422. The additional sub-layer is a titanium sub-layer, has a thickness in the range about 1 nm and 20 nm and functions as an adhesive promotion layer.

FIG. 5 schematically depicts a metallized bonding wire 540 according to yet another exemplary embodiment. In particular, the metallized bonding wire 540 comprises as well a metallic core 521, for example made of copper, and a surface metallization or corrosion protection layer 541 made of titanium and having a thickness of about 1 nm to 20 nm.

Summarizing exemplary embodiments may provide a metallized electric component comprising a metallization structure comprising a surface metallization layer comprising or substantially consisting of gold and silver, while substantially no palladium is used in the whole metallization structure. The use of a gold/silver surface metallization layer while omitting palladium may provide an improved performance of a packaged electronic module the metallized electric component is used in. In particular, the adhesion of an organic molding compound or material to the metallized electronic component may be improved even after a high number of thermocycles. Furthermore, the gold/silver alloy or mixture may exhibit a good bonding capability, i.e. bonding wires, e.g. copper and/or gold, may be readily stick to the surface metallization layer. Furthermore, the electronic module may have an improved resistance against detrimental effects caused by sulfur and/or oxide present in the encapsulation or environment due to the avoiding of catalytic effects of the palladium.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A metallized electric component for an electronic module, the metallized electric component comprising:
a conductive electric element; and
a metallization structure arranged over the conductive electric element and comprising at least a surface metallization layer,
wherein the surface metallization layer comprises an alloy of gold and silver and has a thickness between 1 nm and 100 nm.

2. The metallized electric component according to claim 1, wherein the metallization structure is palladium-free.

3. The metallized electric component according to claim 1, wherein the mass ratio between gold and silver in the surface metallization layer is in the range of 1 to 2 through 5 to 1.

4. The metallized electric component according to claim 1, wherein the metallization structure comprises a sub-layer comprising titanium.

5. The metallized electric component according to claim 4, wherein the sub-layer comprising titanium has a thickness between 1 nm and 20 nm.

6. The metallized electric component according to claim 1, wherein the electric element is an electronic chip.

7. The metallized electric element according to claim 6, wherein the metallization structure is palladium-free.

8. The metallized electric component according to claim 1, wherein the electric element is a bonding wire.

9. The metallized electric component according to claim 8, wherein the bonding wire comprising a metallic core and the metallization structure is arranged around the metallic core.

10. The metallized electric component according to claim 9, wherein the metallic core comprises copper.

11. The electric component according to claim 9, wherein the metallization structure comprising a sub-layer comprising titanium, which is arranged between the metallic core and the surface metallization layer.

12. An electronic module comprising:
a metallized electric component according to claim 1; and
an encapsulation at least partially encapsulating the metallized electric component.

13. The electronic module according to claim 12, wherein the metallized electric component is an electronic chip,
wherein the electronic module further comprises a bonding wire bonded to the surface metallization layer.

14. The electronic module according to claim 12, wherein the electric component is a bonding wire,
wherein the electronic module further comprises an electronic chip comprising a bond pad, wherein the bonding wire is bonded to the bond pad.

15. A bonding wire for an electronic module, the bonding wire comprising:
a copper core; and
an outer corrosion protection layer comprising as a material at least one material selected out of the group consisting of
titanium; and
an alloy of gold and silver,
wherein the outer corrosion protection layer is arranged around the copper core.

16. The bonding wire according to claim 15, wherein the outer corrosion protection layer comprises an alloy of gold and silver and a titanium layer is arranged between the copper core and the outer corrosion protection layer.

17. The bonding wire according to claim 15, wherein the outer corrosion protection layer comprises an alloy of gold and silver, wherein the mass ratio between gold and silver in the surface metallization layer is in the range of 1 to 2 through 5 to 1.
